(19) United States
(12) Patent Application Publication
(10) Pub. No.: US 2025/0040353 A1
(43) Pub. Date: Jan. 30, 2025

(54) DISPLAY PANEL, MANUFACTURING METHOD, AND DISPLAY DEVICE

(71) Applicants: Hefei BOE Joint Technology Co., Ltd., Hefei, Anhui (CN); BOE Technology Group Co., Ltd., Beijing (CN)

(72) Inventors: Wenbin JIA, Beijing (CN); Zhijie YE, Beijing (CN)

(21) Appl. No.: 18/696,953

(22) PCT Filed: Jul. 5, 2023
(86) PCT No.: PCT/CN2023/105830

§ 371 Date: Mar. 28, 2024

(30) Foreign Application Priority Data
Jul. 27, 2022 (CN) 202210889014.8

(51) Int. Cl. H10K 59/122; H10K 59/12

(52) U.S. Cl. CPC H10K 59/122; H10K 59/1201

(57) ABSTRACT

A display panel, a manufacturing method, and a display device are provided. The display panel includes a substrate and a pixel definition layer. The pixel definition layer includes multiple first barrier walls extending along a first direction and arranged along a second direction and multiple second barrier walls extending along the second direction and arranged along the first direction. The first direction and the second direction intersect. The first barrier walls include two edge barrier walls at two edges along the second direction, multiple intermediate barrier walls between the two edge barrier walls, and two separation barrier walls between the two edge barrier walls and respectively on two sides of the intermediate barrier walls along the second direction. The heights of the second barrier walls, the edge barrier walls and the separation barrier walls each is greater than the height of the intermediate barrier wall.

### CROSS REFERENCE TO RELATED APPLICATION

This application is a National Stage of International Application No. PCT/CN2023/105830 filed Jul. 5, 2023, which claims priority to Chinese patent application No. 202210889014.8, filed with the China National Intellectual Property Administration on Jul. 27, 2022 and entitled “DISPLAY PANEL, MANUFACTURING METHOD, AND DISPLAY DEVICE”, the entire contents of which are incorporated herein by reference.

### TECHNICAL FIELD

The present disclosure relates to the field of display technology, and in particular to a display panel, a manufacturing method, and a display device.

### BACKGROUND

Compared with the liquid crystal display (LCD), the organic electroluminescent display (OLED) panel has the advantages of self-illumination, fast response, wide viewing angle, high brightness, bright colors, and thinness, etc., and is considered to be a panel with the next generation display technology.

The film formation methods of OLED mainly include evaporation method and inkjet-printed (IJP) method. The film formation process using the evaporation method is relatively mature in the production of small-size OLEDs. However, due to the limitation of mask accuracy, the evaporation process has a low material utilization rate and is difficult to achieve the production of large-size OLEDs. The film formation process using the inkjet-printed method has become a hot research topic due to its advantages of fast film formation speed, high material utilization rate, and the ability to produce large-size OLEDs. Currently, the use of the inkjet-printed method to produce OLEDs still has the problem of uneven film thickness of pixel units.

### SUMMARY

The present disclosure provides a display panel, a manufacturing method, and a display device to improve the problem of uneven film thickness of inkjet-printed organic electroluminescent display panels.

A first aspect of the present disclosure provides a display panel, including:
a substrate;
a pixel definition layer, located on the substrate; wherein the pixel definition layer includes:
a plurality of first barrier walls, extending along a first direction and arranged along a second direction, wherein the first direction and the second direction intersect; and
a plurality of second barrier walls, extending along the second direction and arranged along the first direction, wherein the plurality of first barrier walls and the plurality of second barrier walls define a plurality of openings for defining pixel units, one pixel unit corresponds to one opening, and the pixel unit is located in the corresponding opening;
wherein the plurality of first barrier walls include:
two edge barrier walls, wherein the two edge barrier walls are respectively the first barrier walls at two edges along the second direction;
a plurality of intermediate barrier walls, located between the two edge barrier walls; and
two separation barrier walls, located between the two edge barrier walls and respectively located on both sides of the plurality of intermediate barrier walls along the second direction;
wherein heights of the second barrier wall, the edge barrier wall and the separation barrier wall are all greater than a height of the intermediate barrier wall.

In the display panel provided in the present disclosure, the second barrier wall, the edge barrier wall and the separation barrier wall have equal heights.

In the display panel provided in the present disclosure, the second barrier wall has a height of 0.6 μm to 1.5 μm, and the intermediate barrier wall has a height of 0.2 μm to 0.5 μm.

In the display panel provided in the present disclosure, the plurality of first barrier walls further include:
at least one spacing barrier wall, located between the edge barrier wall and the separation barrier wall on at least one side along the second direction;
wherein a height of the spacing barrier wall is equal to the height of the second barrier wall; or, a height of the spacing barrier wall is equal to the height of the intermediate barrier wall.

In the display panel provided in the present disclosure, the plurality of first barrier walls include a plurality of spacing barrier walls, and the plurality of spacing barrier walls are respectively located between the edge barrier walls and the separation barrier walls on both sides along the second direction;
a quantity of the spacing barrier walls between the edge barrier walls and the separation barrier walls on the both sides along the second direction is equal; and
the height of the spacing barrier wall is equal to the height of the second barrier wall.

In the display panel provided in the present disclosure, colors of emergent light of the pixel units adjacent in the second direction are the same, and colors of emergent light of the pixel units adjacent in the first direction are different.

In the display panel provided in the present disclosure, the pixel units are divided into first pixel units and second pixel units; the second pixel units are distributed on both sides of the first pixel units along the second direction;
the first pixel unit includes an anode, a light emitting layer and a cathode arranged in sequence in the corresponding opening; the second pixel unit includes a light emitting layer and a cathode arranged in sequence in the corresponding opening;
the pixel units located between the two separation barrier walls are the first pixel units.

In the display panel provided in the present disclosure, the pixel units located between the separation barrier walls and the edge barrier walls on both sides along the second direction are the second pixel units.

In the display panel provided in the present disclosure, at least one row of pixel units located between the separation barrier wall and the edge barrier wall on at least one side along the second direction and adjacent to the separation barrier wall are the first pixel units; and the at least one row of pixel units is at least one row of pixel units arranged along the first direction.

In the display panel provided in the present disclosure, the first barrier wall located between the adjacent first pixel units and the second pixel units is a spacing barrier wall, and a height of the spacing barrier wall is greater than the height of the intermediate barrier wall.

In the display panel provided in the present disclosure, a quantity of the second pixel units arranged along the second direction and located on any side of the first pixel units along the second direction is less than 6.

A second aspect of the present disclosure provides a display device including the display panel according to any one of the above display panels.

A third aspect of the present disclosure provides a method for manufacturing a display panel, including:
forming an anode of each pixel unit on a substrate;
forming a pixel definition layer on the substrate; wherein the pixel definition layer includes: a plurality of first barrier walls and a plurality of second barrier walls; the plurality of first barrier walls extend along a first direction and are arranged along a second direction, the plurality of second barrier walls extend along the second direction and are arranged along the first direction; the first direction and the second direction intersect; the plurality of first barrier walls and the plurality of second barrier walls define a plurality of openings, and one opening corresponds to one anode; and
forming a light emitting layer and a cathode of each pixel unit on one side of the anode and the pixel definition layer facing away from the substrate;
wherein the plurality of first barrier walls include: two edge barrier walls, a plurality of intermediate barrier walls and two separation barrier walls; the two edge barrier walls are respectively the first barrier walls at both edges along the second direction; the plurality of intermediate barrier walls are located between the two edge barrier walls; the two separation barrier walls are located between the two edge barrier walls and are respectively located on both sides of the plurality of intermediate barrier walls along the second direction; and the heights of the second barrier wall, the edge barrier wall and the separation barrier wall are all greater than a height of the intermediate barrier wall.

In the method provided in the present disclosure, the forming of the pixel definition layer on the substrate includes:
forming an entire lyophilic material layer on the substrate;
etching the lyophilic material layer to form the plurality of intermediate barrier walls;
forming an entire lyophobic material layer on one side of the plurality of intermediate barrier walls facing away from the substrate; and
etching the lyophobic material layer to form the plurality of second barrier walls, the two edge barrier walls and the two separation barrier walls; wherein the second barrier wall, the edge barrier wall and the separation barrier wall have equal heights.

In the method provided in the present disclosure, the plurality of first barrier walls further include: at least one spacing barrier wall; the at least one spacing barrier wall is located between the edge barrier wall and the separation barrier wall on at least one side along the second direction;
when a height of the spacing barrier wall is equal to the height of the intermediate barrier wall, the forming of the pixel definition layer on the substrate further includes:
etching the lyophilic material layer to form the plurality of intermediate barrier walls and the at least one spacing barrier wall;
when the height of the spacing barrier wall is equal to the height of the second barrier wall, the forming of the pixel definition layer on the substrate further includes:
etching the lyophobic material layer to form the plurality of second barrier walls, the two edge barrier walls, the two separation barrier walls and the at least one spacing barrier wall.

In the method provided in the present disclosure, the forming of the light emitting layer of each pixel unit on one side of the anode and the pixel definition layer facing away from the substrate includes:
inkjet printing solution of the light emitting layer on the anode and the first barrier wall along the second direction; and
drying the solution of the light emitting layer to form the light emitting layer.

### BRIEF DESCRIPTION OF FIGURES

In order to illustrate the technical solutions of the embodiments of the present disclosure more clearly, the drawings required to be used in the embodiments of the present disclosure will be briefly introduced below. Obviously, the drawings introduced below are only some embodiments of the present disclosure. Those of ordinary skill in the art can also obtain other drawings based on these drawings without exerting creative efforts.

FIG. 1 is a structural schematic diagram of a pixel definition layer in the related art.

FIG. 2 is a first schematic structural diagram of a display panel provided by an embodiment of the present disclosure.

FIG. 3 is a schematic cross-sectional structural diagram of a pixel unit provided by an embodiment of the present disclosure.

FIG. 4A is a second structural schematic diagram of a display panel provided by an embodiment of the present disclosure.

FIG. 4B is a third structural schematic diagram of a display panel provided by an embodiment of the present disclosure.

FIG. 5 is a fourth structural schematic diagram of a display panel provided by an embodiment of the present disclosure.

FIG. 6 is a flow chart of a method for manufacturing a display panel provided by an embodiment of the present disclosure.

Reference numerals: D-pit, R-barrier wall, 1-substrate, 2-pixel definition layer, 21-first barrier wall, 211-edge barrier wall, 212-separation barrier wall, 213-intermediate barrier wall, 214-spacing barrier wall, 214a-first spacing barrier wall, 214b second spacing barrier wall, 22-second barrier wall, S1-first area, S2-second area, S3-third area, K-opening, P-pixel unit, A-anode, H-anode functional layer, H1-hole injection layer, H2-hole transport layer, L-light emitting layer, E-cathode functional layer, E1-electron injection layer, E2-electron transport layer, C-cathode.

### DETAILED DESCRIPTION

In order to make the above objects, features and advantages of the present disclosure more apparent and understandable, the present disclosure will be further described below in conjunction with the accompanying drawings and embodiments. Implementation embodiments may, however, be embodied in various forms and should not be construed as limited to the embodiments set forth herein, rather, the provision of these embodiments makes the present disclosure more comprehensive and complete and conveys the idea of the embodiments in a comprehensive manner to those skilled in the art. The same reference numerals in the drawings represent the same or similar structures, and thus their repeated description will be omitted. The words described in this disclosure to express position and orientation are illustrated by way of example in the accompanying drawings, but changes may be made as needed, and the changes are included in the scope of protection of the present disclosure. The accompanying drawings of the present disclosure are only used to illustrate the relative positional relationship but not to represent the true proportion.

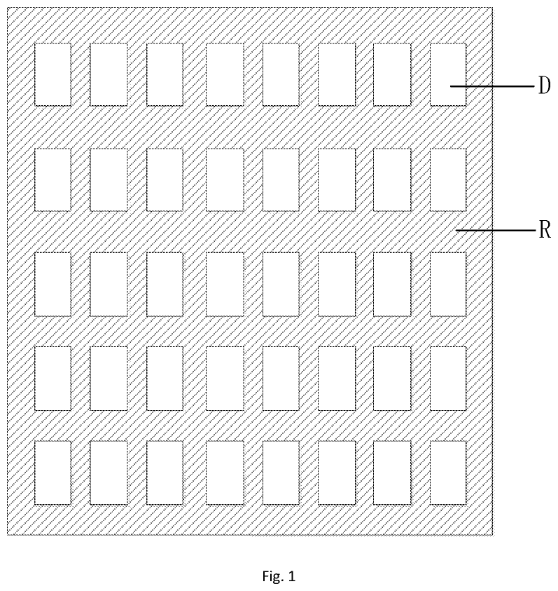

FIG. 1 is a structural schematic diagram of a pixel definition layer in the related art.

When manufacturing an OLED using the traditional inkjet-printed method, it is usually necessary to prepare a pixel definition layer on a substrate, and then inkjet-printed solutions of a light emitting layer and/or a functional layer in the pixel definition layer to form pixel units. As shown in FIG. 1, the current pixel definition layer includes multiple pits D arranged in an array. The pixel units each is provided in a respective one of the pits D. Adjacent pits D are isolated from each other by barrier walls R of the same height. During production, the solution to be printed in a nozzle of a print head needs to be precisely dropped into the corresponding pit D, and it is necessary to ensure that the volumes of the solutions dropped into respective pits D are the same, thereby ensuring that film thicknesses in each pit are equal. As the resolution of OLED increases, the number of pits D in the pixel definition layer on the substrate of the same size increases greatly, and the opening of the pit D becomes smaller. When performing inkjet printing, it is difficult to ensure the precise dripping of the solution for the pixel unit due to the precision of the print head, and the volume of solution dripping for the pixel unit in each pit is difficult to control, which can lead to Suji Mura. And due to the smaller pixel opening, a very obvious coffee ring effect with thicker edges and thinner center of the film layer will be caused in the pixel unit during the solution drying process, and the uniformity of film formation cannot be guaranteed.

In view of this, a first aspect of the present disclosure provides a display panel that can significantly ameliorate the problem of uneven film formation during inkjet printing.

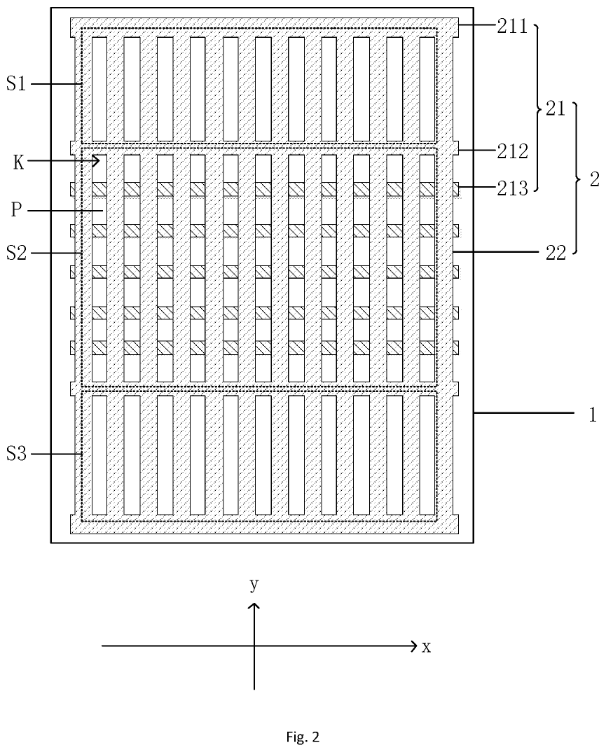

FIG. 2 is a first schematic structural diagram of a display panel provided by an embodiment of the present disclosure.

As shown in FIG. 2, in the embodiments of the present disclosure, the display panel includes: a substrate 1 and a pixel definition layer 2.

The substrate 1 is at a bottom of the display panel and plays a role of carrying and driving. The shape of the substrate 1 is adapted to the shape of the display panel. In implementations, the shape of the substrate 1 may be square or rectangular. When applied to special-shaped displays, the shape of the substrate 1 may also be circular or other shapes. This will not be limited herein.

In implementations, the substrate 1 may include a base substrate and a driving circuit layer formed on the base substrate.

Here, the base substrate may be made of any appropriate material suitable for the structure of the display panel. For example, when applied to a non-transparent display, the substrate 1 may be made of a non-transparent material; when applied to a transparent display, the substrate 1 may be made of a transparent material such as glass and transparent resin, etc.; and when applied to a flexible display, the substrate 1 may be made of flexible resin or other materials. This will not be limited herein.

The driving circuit layer is located on the base substrate and is used to provide driving signals. In some embodiments, the substrate 1 may be a thin film transistor (TFT) substrate. The driving circuit layer includes multiple signal lines and multiple TFTs produced through an array process. A pixel circuit that is constituted by signal lines, TFTs, resistors, capacitors, etc., is used to implement active driving, which is not limited herein.

The pixel definition layer 2 is located on the substrate 1. In implementations, the pixel definition layer 2 may be located on a side of the driving circuit layer facing away from the base substrate.

As shown in FIG. 2, the pixel definition layer 2 includes a plurality of first barrier walls 21 extending along a first direction x and arranged along a second direction y and a plurality of second barrier walls 22 extending along the second direction y and arranged along the first direction x. Here, the first direction x and the second direction y intersect with each other.

The plurality of first barrier walls 21 and the plurality of second barrier walls 22 define a plurality of openings K for defining pixel units P. One pixel unit P corresponds to one opening K, and the pixel unit P is located in the corresponding opening K. In implementations, the pixel unit P is driven through the substrate 1 to emit light to achieve image display.

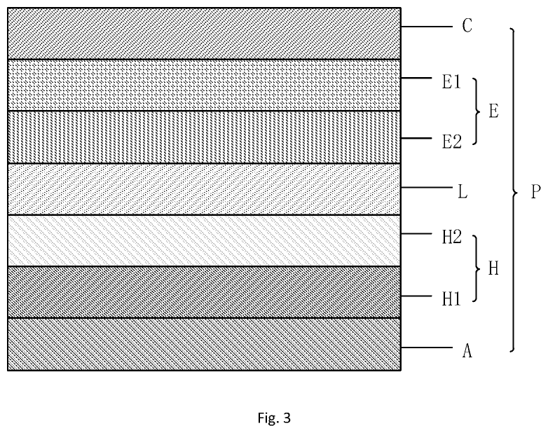

FIG. 3 is a schematic cross-sectional structural diagram of a pixel unit provided by an embodiment of the present disclosure.

In embodiments of the present disclosure, the display panel is an organic light-emitting display panel, and the pixel unit P may use an OLED device. As shown in FIG. 3, the OLED device includes at least an anode A, a light emitting layer L, and a cathode C that are stacked in sequence. The OLED device generates excitons through the compounding of holes provided by the anode A and electrons provided by cathode C in the light emitting layer L, thereby radiating light. In implementations, the pixel unit P may also include an anode functional layer H located between the anode A and the light emitting layer L for improving hole transmission efficiency, and a cathode functional layer E located between the cathode C and the light emitting layer EL for improving electron transmission efficiency. The anode functional layer H may include a hole injection layer H1 located on a surface of the anode A and a hole transport layer H2 located on one side of the hole injection layer H1 facing away from the anode A. The cathode functional layer E may include an electron injection layer E1 located on the surface of the cathode C, and an electron transport layer E2 located on one side of the electron injection layer E2 facing away from the cathode C. During production, the light emitting layer L and/or the anode functional layer H of the OLED device can be produced by inkjet printing.

The plurality of first barrier walls 21 include at least: two edge barrier walls 211, a plurality of intermediate barrier walls 213 and two separation barrier walls 212. Among them, the two edge barrier walls 21 are first barrier walls at two edges along the second direction y. The plurality of intermediate barrier walls 213 are located between the two edge barrier walls 21. The two separation barrier walls 212 are located between the two edge barrier walls 211 and respectively located on both sides of the plurality of intermediate barrier walls 213 along the second direction y. Here, the heights of the second barrier wall 22, the edge barrier wall 211 and the separation barrier wall 212 each is greater than the height of the intermediate barrier wall 213.

In some embodiments of the present disclosure, the intermediate barrier wall 213 with a lower height may be made of a lyophilic material, and the barrier wall with a higher height may be made of a lyophobic material. And when manufacturing OLED devices, inkjet printing can be performed along the second direction y.

Here, the edge barrier walls 211 and the separation barrier walls 212 may divide multiple pixel units P into three areas. As shown in FIG. 2, an area between the two separation barrier walls 212 is a second area S2. Areas between the separation barrier wall 212 and the edge barrier wall 211 on both sides are respectively a first area S1 and a third area S3. The first area S1 and the third area S3 are located on both sides of the second area S2. Since only the intermediate barrier walls 213 are provided in the second area S2, the height of the intermediate barrier wall 213 is lower than the height of the second barrier wall 22, the intermediate barrier wall is made of the lyophilic material, and the second barrier wall 22 is made of the lyophobic material, during the process of inkjet printing along the second direction y, the solutions can flow toward two adjacent openings K along the second direction y to form the same film layer, while two adjacent openings K along the first direction x are separated by a higher second barrier wall, so that the solutions cannot flow therebetween.

During production, the solutions of pixel units of the same color is printed in the same column of pixel units P in the second direction y, and the solutions of pixel units of different colors are printed in the adjacent columns of pixel units in the first direction x, thereby achieving color display. Specifically, along the second direction y, the solutions are printed into the same column of openings K and cover the surface of the intermediate barrier walls 213. The printed solutions in the second area S2 diffuse with each other, thereby forming a uniform film layer. Compared with the related art, using the structure of the display panel provided by the embodiments of the present disclosure, the accuracy requirements for the alignment of the nozzle of the print head and the opening K during inkjet printing are lower, and the solutions printed by respective nozzles are uniformly mixed during the flow and diffusion process along the second direction y, and the film thickness uniformity of the pixel units P in the second area S2 will not be affected by different volumes of solutions printed by different nozzles. Along the first direction x, the solutions in adjacent columns are blocked by the second barrier wall 22, and the solutions in adjacent columns will not contact each other, thus preventing color contamination problems.

Since during the drying process of the solutions, the solutions in the edge areas of the pixel definition layer 2 dry faster, and the solutions in the intermediate area of the pixel definition layer 2 dry slower, differences in solution drying rates in different areas tend to cause uneven film formation.

Therefore, in embodiments of the present disclosure, two separation barrier walls 212 are provided on both sides of the plurality of intermediate barrier walls 213. The two separation barrier walls separate the second area S2 located in the middle of the pixel definition layer 2 from the first area S1 and the third area S3 located at the edges, to prevent the solutions of the pixel units in the second area S2 from flowing to the edge areas. Then, during the drying process, the flow of the solutions from the middle area to the edge areas due to the solvent evaporating too quickly from the solutions in the edge areas can be avoided, further ensuring the uniformity of the film thickness in the second area S2.

In some embodiments, the intermediate barrier wall 213 may be made of a lyophilic material, and the second barrier wall 22, edge barrier wall 211 and separation barrier wall 212 may all be made of a lyophobic material, so that during the inkjet-printed process, it is possible to ensure the fluidity of the solutions in the pixel units in the second area S2 flowing to both sides along the second direction y, while avoiding the mixing of the solutions in two adjacent openings K along the first direction x.

In implementations, an entire lyophilic material layer may be formed on the substrate 1 first, and patterns of the plurality of intermediate barrier walls 213 may be formed by etching. Then an entire lyophobic material layer may be formed on one side of the plurality of intermediate barrier walls 213 facing away from the substrate 1, and patterns of the second barrier wall 22, the edge barrier wall 211 and the separation barrier wall 212 are formed by etching. The heights of the second barrier wall 22, the edge barrier wall 211 and the separation barrier wall 212 formed in this way are the same. The second barrier wall 22, the edge barrier wall 211 and the separation barrier wall 212 may also be manufactured separately, which are not limited herein. Here, the second barrier wall 22 is formed on the substrate and the lyophilic material layer, and the edge barrier wall 211 and the separation barrier wall 212 may be directly formed on the lyophilic material layer, or may be formed directly on the substrate, which are not limited herein. By controlling the thicknesses of the lyophilic material layer and the lyophobic material layer, the height of the second barrier wall ranges from 0.6 μm to 1.5 μm, and the height of the intermediate barrier wall ranges from 0.2 μm to 0.5 μm.

In embodiments of the present disclosure, the first barrier wall 21 further includes at least one spacing barrier wall. The spacing barrier wall is located between the edge barrier wall and the separation barrier wall on at least one side in the second direction. The spacing barrier walls are used to define the shapes and sizes of the pixel units in the first area S1 and the third area S3 to be the same as the pixel units in the second area S2.

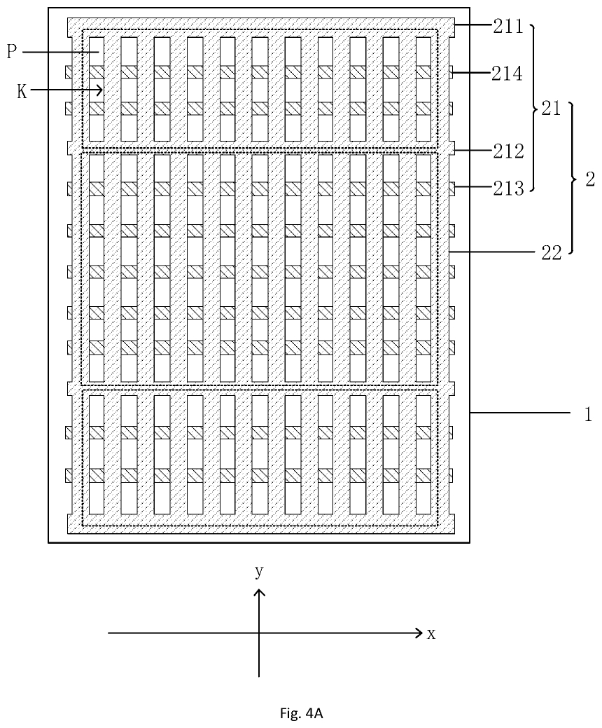

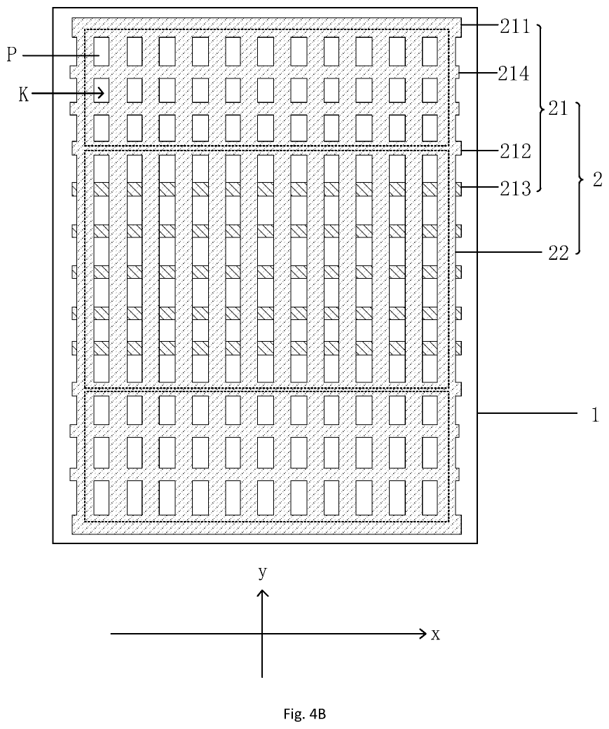

FIG. 4A is a second structural schematic diagram of a display panel provided by an embodiment of the present disclosure. FIG. 4B is a third structural schematic diagram of a display panel provided by an embodiment of the present disclosure.

In some embodiments, as shown in FIG. 4A and FIG. 4B, at least one spacing barrier wall 214 is provided between the edge barrier walls 211 and the separation barrier walls 212 on both sides in the second direction y respectively. Here, as shown in FIG. 4A, the height of the spacing barrier wall 214 is equal to the height of the intermediate barrier wall 213. During manufacturing, the spacing barrier wall 214 and the intermediate barrier wall 213 may be manufactured simultaneously, which is not limited herein. Alternatively, as shown in FIG. 4B, the height of the spacing barrier wall 214 is equal to the height of the second barrier wall 22. During manufacturing, the spacing barrier wall 214 and the second barrier wall 22 may be manufactured simultaneously, which is not limited herein.

When the height of the spacing barrier wall 214 is set equal to the height of the second barrier wall 22, in the second direction y, the spacing barrier wall 214 may enhance separation for the printing solutions between the edge barrier wall 211 and the separation barrier wall 212. During the drying process of the solutions, the solvent of the inkjet-printed solutions near the edge of the pixel definition layer 2 evaporates quickly, due to the addition of the spacing barrier 214, it has a blocking effect on solutions so that the solutions in the middle of the pixel definition layer 2 will not flow to the edge, thereby ensuring that the concentration of the solutions in the middle of the pixel definition layer 2 is similar, and the solvent vapor pressure atmosphere of the solutions is similar, thereby ensuring that the volatilization rate of the solvent from the solutions in the larger middle area of the pixel definition layer 2 is similar, and the solutions are dried to obtain a uniform film layer. When the height of the spacing barrier wall 214 is the same as each of the heights of the edge barrier wall 211 and the separation barrier wall 212, during the production process, the spacing barrier wall 214 may be manufactured simultaneously with the second barrier wall 22, the edge barrier wall 211 and the separation barrier wall 212. This is not limited herein.

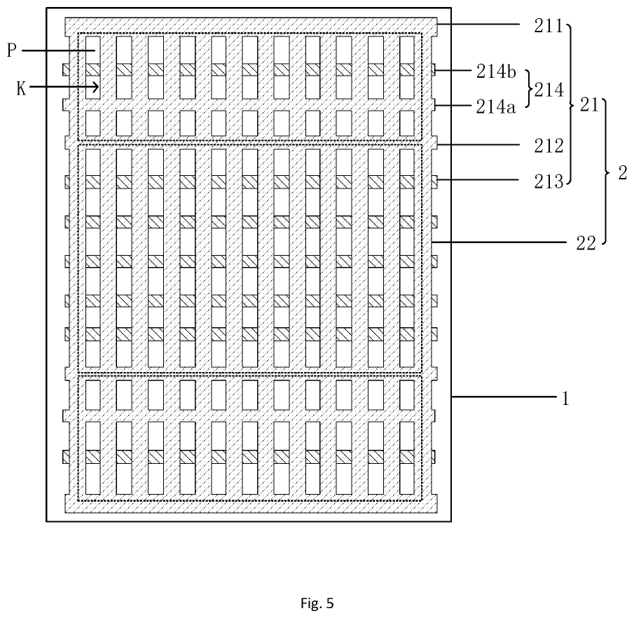

FIG. 5 is a fourth structural schematic diagram of a display panel provided by an embodiment of the present disclosure.

In some embodiments, as shown in FIG. 5, the spacing barrier wall 214 may include a first spacing barrier wall 214a and a second spacing barrier wall 214b. Here, the height of the second spacing barrier wall 214b is the same as the height of the intermediate barrier wall 213, and the height of the first spacing barrier wall 214a is greater than the height of the intermediate barrier wall 213. On at least one side in the second direction y, at least one spacing barrier wall 214 adjacent to the separation barrier wall 212 is the first spacing barrier wall 214a.

During implementations, the height of the spacing barrier wall 214 may be adjusted according to the film formation thickness. The heights of the spacing barrier walls 214 on any side may be the same or different. The spacing barrier walls 214 on both sides can be arranged symmetrically or asymmetrically, which is not limited herein.

As shown in FIG. 4A, FIG. 4B and FIG. 5, the number of spacing barrier walls 214 provided in the first area S1 and the third area S3 may be determined based on a distance between the edge barrier wall 211 and the separation barrier wall 212 and a size of the pixel unit. Generally, the shapes and sizes of the pixel units in the first area S1 and the third area S3 are the same as those of the pixel units in the second area S2. In FIG. 4A and FIG. 4B, two spacing barrier walls 214 are provided on each side for illustration, and the number of spacing barrier walls is not limited.

It should be noted that in embodiments of the present disclosure, the pixel units in the display panel may be divided into first pixel units and second pixel units. The first pixel units are used for image display. The second pixel units are located around the first pixel units and do not used for image display, but is used to expand the film formation area of inkjet printing, to ensure the uniformity of film formation in the first pixel units.

When the structure of the display panel provided by the embodiments of the present disclosure is adopted, the thickness of the film layer in the middle area of the pixel definition layer is relatively uniform during the inkjet-printed process. Therefore, the pixel units in this area may be set as the first pixel units, and the pixel units in the area where film uniformity cannot be guaranteed are set as the second pixel units.

During implementations, the first pixel unit may adopt an OLED device, and the first pixel unit includes an anode, a light emitting layer and a cathode sequentially arranged in the corresponding opening of the pixel definition layer. The second pixel unit may adopt a structure similar to the OLED device, and the second pixel unit includes a light emitting layer and a cathode that are sequentially arranged in the corresponding opening of the pixel unit, so that the first pixel unit can be used for image display, and the second pixel unit is not used for image display.

During production, the anode, light emitting layer and cathode may also be arranged in sequence in the opening of the pixel definition layer corresponding to the second pixel unit, but a pixel circuit is not formed in the substrate at the corresponding position of the second pixel unit. Alternatively, the structure and the pixel circuit of the second pixel unit are the same as those of the first pixel unit. During image display, the driving signal is only applied to the first pixel unit for image display, and the driving signal is not applied to the second pixel unit. Moreover, the first pixel unit and the second pixel unit each may include an anode functional layer and a cathode functional layer, which are not limited herein.

In embodiments of the present disclosure, the height of the first barrier wall between the first pixel unit and the second pixel unit is greater than the height of the intermediate barrier wall 213. That is, a higher first barrier wall is used to separate the first pixel unit and the second pixel unit, thereby avoiding the problem of uneven film thickness in the solution film formation process in the area where the first pixel unit is located during inkjet printing.

In some embodiments, each pixel unit P (i.e., the pixel unit in the second area S2) between the two separation barrier walls 212 may be set as the first pixel unit, and each pixel unit P (i.e., the pixel unit in the first area S2 and the third area S3) between the separation barrier wall 212 and the edge barrier wall 211 on both sides in the second direction may be set as the second pixel unit. That is, the first barrier wall that is used to separate the first pixel unit and the second pixel unit is the separation barrier wall 212.

Using two separation barrier walls 212 to limit the printing solutions may ensure that the printing solutions can flow evenly between the intermediate barrier walls while preventing the printing solutions located in the middle area from flowing rapidly to the edges, ensuring the film thickness uniformity of the printing solutions in the area where the first pixel units are located.

In some embodiments, each pixel unit P (i.e., the pixel unit in the second area S2) between the two separation barrier walls 212 may be set as the first pixel unit. In addition, at least one row of pixel units between the separation barrier wall 212 and the edge barrier wall 211 and adjacent to the separation barrier wall 212 may also be set as the first pixel unit, and other pixel units between the separation barrier wall 212 and the edge barrier wall 211 are set as second pixel units. In such a case, the first barrier wall used to separate the first pixel unit and the second pixel unit is a spacing barrier wall, and the height of the spacing barrier wall is greater than the height of the intermediate barrier wall.

Since several spacing barrier walls are provided between the separation barrier wall 212 and the edge barrier wall 211, the printing solutions around the separation barrier wall 212 have better film thickness uniformity, so that at least one row of pixel units P in the first area S1 and the third area S3 adjacent to the separation barrier wall 212 is also set as the first pixel unit, thereby increasing the area of the display area. Here, at least one row of pixel units is at least one row of pixel units arranged along the first direction x.

In embodiments of the present disclosure, in the second direction y, the number of second pixel units located on any side may be less than 6. The number of second pixel units is related to the number of spacing barrier walls. In implementations, the number of spacing barrier walls may be set according to the film formation uniformity to make the film thickness uniform after inkjet printing in the area where the first pixel unit located in the middle area is located. The number of the second pixel units located on both sides is not limited in the embodiments of the present disclosure.

A second aspect of the present disclosure provides a display device, which includes any of the above display panels. In implementations, the display device may be a smartphone, a television, a flat panel display, a computer monitor, a billboard, a transparent display, a theater screen, etc. using any of the above display panels, and is not limited here. Since the problem-solving principle of the display device is similar to that of the above-mentioned display panel, the implementation of the display device may refer to the implementation of the above-mentioned display panel, and repeated details will not be repeated.

A third aspect of the present disclosure provides a method for manufacturing a display panel.

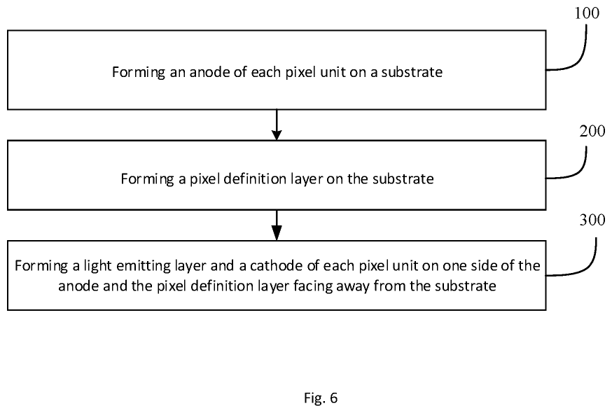

FIG. 6 is a flow chart of a method for manufacturing a display panel provided by an embodiment of the present disclosure.

As shown in FIG. 6, the method for manufacturing a display panel provided by an embodiment of the present disclosure includes the following operations.

Operation S100: forming an anode of each pixel unit on a substrate.

Operation S200: forming a pixel definition layer on the substrate.

Operation S300: forming a light emitting layer and a cathode of each pixel unit on one side of the anode and the pixel definition layer facing away from the substrate.

In the process of manufacturing a display panel, a substrate is first manufactured. The substrate is used to drive pixel units to emit light. In implementations, the substrate may include a base substrate and a driving circuit layer located on a surface of the base substrate. The driving circuit layer is used to provide driving signals. After the substrate is produced, anodes of each pixel unit are formed on the substrate at corresponding positions through spin coating, deposition, evaporation, etching, etc. The anode material may be traditional anode materials such as indium tin oxide, which is not limited herein. In embodiments of the present disclosure, the pixel units are divided into first pixel units and second pixel units. The first pixel units are used for image display, and the second pixel units are located around the first pixel units and are not used for image display, but to expand the film formation area of inkjet printing to ensure the uniformity of film formation of the first pixel units. During implementations, the anode may be formed only at the position corresponding to the first pixel unit, or the anode may be formed at both the positions corresponding to the first pixel unit and the second pixel unit, which is not limited herein.

After the anode is produced, a pixel definition layer is formed on the substrate. The pixel definition layer includes: a plurality of first barrier walls and a plurality of second barrier walls. The plurality of first barrier walls extend along the first direction and are arranged along the second direction, and the plurality of second barrier walls extend along the second direction and are arranged along the first direction. The first direction and the second direction intersect. The plurality of first barrier walls and the plurality of second barrier walls define multiple openings. One opening corresponds to one anode. In implementations, the plurality of first barrier walls include: two edge barrier walls, a plurality of intermediate barrier walls and two separation barrier walls. The two edge barrier walls are respectively the first barrier walls on both sides along the second direction. The plurality of intermediate barrier walls are located between the two edge barrier walls. The two separation barrier walls are located between the two edge barrier walls and are respectively located on both sides of the plurality of intermediate barrier walls along the second direction. The heights of the second barrier wall, the edge barrier wall and the separation barrier wall each is greater than the height of the intermediate barrier wall.

After the pixel definition layer is formed, the pixel unit is formed in the opening of the pixel definition layer. During implementations, the pixel unit may be an OLED device. As shown in FIG. 3, the OLED device includes at least an anode A, a light emitting layer L and a cathode C that are stacked in sequence. During the production process, the light emitting layer L of each pixel unit may be formed on one side of the anode and the pixel definition layer facing away from the substrate through inkjet printing, and then the cathode C may be formed on one side of the light emitting layer L facing away from the anode A through evaporation or other methods.

In implementations, as shown in FIG. 2, the edge barrier walls 211 and the separation barrier walls 212 may divide the pixel units P into three areas. As shown in FIG. 2, the area between the two separation barrier walls 212 is the second area S2, and the areas between the separation barrier wall 212 and the edge barrier wall 211 on both sides are the first area S1 and the third area S3 respectively. The first area S1 and the third area S3 are located on both sides of the second area S2. Since only the intermediate barrier wall 213 is provided inside the second area S2, and the height of the intermediate barrier wall 213 is lower than the height of the second barrier wall 22, during the process of inkjet printing the light emitting layer along the second direction y, the solutions may flow to two adjacent openings K along the second direction y to form the same film layer, while the two adjacent openings K along the first direction x are separated by a higher second barrier wall, so the solutions cannot flow therebetween.

During production, the solutions of pixel units of the same color are printed in the same column of pixel units P in the second direction y, and the solutions of pixel units of different colors are printed in the adjacent columns of pixel units in the first direction x, thereby achieving color display. Specifically, along the second direction y, the solutions are printed into the same column of openings K and cover the surface of the intermediate barrier walls 213. The printed solutions in the second area S2 diffuse with each other, thereby forming a uniform film layer. Compared with the related art, using the structure of the display panel provided by the embodiments of the present disclosure, the accuracy requirements for the alignment of the nozzle of the print head and the opening K during inkjet printing are lower, and the solutions printed by respective nozzles are uniformly mixed during the flow and diffusion process along the second direction y, and the film thickness uniformity of the pixel units P in the second area S2 will not be affected by different volumes of solutions printed by different nozzles. Along the first direction x, the solutions in adjacent columns are blocked by the second barrier wall 22, and the solutions in adjacent columns will not contact each other, thus preventing color contamination problems.

Since during the drying process of the solutions, the solutions in the edge areas of the pixel definition layer 2 dry faster, and the solutions in the intermediate area of the pixel definition layer 2 dry slower, differences in solution drying rates in different areas tend to cause uneven film formation.

Therefore, in embodiments of the present invention, two separation barrier walls 212 are provided on both sides of the plurality of intermediate barrier walls 213. The two separation barrier walls separate the second area S2 located in the middle of the pixel definition layer 2 from the first area S1 and the third area S3 located at the edges, to prevent the solutions of the pixel units in the second area S2 from flowing to the edge areas. Then, during the drying process, the flow of the solutions from the middle area to the edge areas due to the solvent evaporating too quickly from the solutions in the edge areas can be avoided, further ensuring the uniformity of the film thickness in the second area S2.

In some embodiments, when forming the pixel definition layer, an entire lyophilic material layer may be formed on the substrate by means of spin coating, deposition, evaporation, etc. The lyophilic material layer is used to make the intermediate barrier wall with a lower height located between two separation barrier walls. The intermediate barrier is made of the lyophilic material, which is conducive to the material flow of the solutions of the light emitting layer, and is conducive to the uniform mixing of the solutions of the light emitting layer between adjacent openings in the second direction when performing inkjet printing. Then, patterns of multiple intermediate barrier walls are formed on the lyophilic material layer by etching. Next, an entire lyophobic material layer is formed on one side of the multiple intermediate barrier walls facing away from the substrate through spin coating, deposition, evaporation, etc., and the lyophobic material layer is etched to form the plurality of second barrier walls, two edge barrier walls and two separation barrier walls. The heights of the second barrier wall, the edge barrier wall and the separation barrier wall are equal, which is not limited herein.

In some embodiments, the first barrier wall further includes at least one spacing barrier wall. As shown in FIGS. 4A to 5, the spacing barrier wall 214 is formed between the edge barrier wall 211 and the separation barrier wall 212 on at least one side in the second direction y. During implementations, the height of the spacing barrier wall 214 may be equal to the height of the intermediate barrier wall 213. When etching the lyophilic material layer, multiple intermediate barrier walls 213 and at least one spacing barrier 214 may be formed simultaneously. Alternatively, the height of the spacing barrier wall 214 is equal to the height of the second barrier wall 22. When etching the lyophobic material layer, the plurality of second barrier walls 22, two edge barrier walls 211, two separation barrier walls 212, and at least one spacing barrier wall 214 are formed. This is not limited herein.

In some embodiments, when forming the light emitting layer of each pixel unit on one side of the anode and the pixel definition layer away from the substrate, the solutions of the light emitting layer may be inkjet printed on the anode and the first barrier wall along the second direction, and then the solutions of the light emitting layer are dried to form the light emitting layer.

In some embodiments, as shown in FIG. 3, the pixel unit P further includes an anode functional layer H between the anode A and the light emitting layer L, and a cathode functional layer E between the cathode C and the light emitting layer L. During implementations, the anode functional layer H and the light emitting layer L may be sequentially formed on the anode and the first barrier walls along the second direction by inkjet printing, and then the cathode functional layer E and the cathode C may be sequentially formed by evaporation. This is not limited herein.

During implementations, the method for manufacturing the display panel provided by the embodiments of the present disclosure and the above-mentioned embodiments of the display panels can be referred to each other, and will not be repeated herein.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the present disclosure.

Obviously, those skilled in the art can make various changes and modifications to the present disclosure without departing from the spirit and scope of the disclosure. In this way, if these modifications and variations of the present disclosure fall within the scope of the claims of the present disclosure and equivalent technologies, the present disclosure is also intended to include these modifications and variations.

1. A display panel, comprising:
a substrate;
a pixel definition layer on the substrate;
wherein the pixel definition layer comprises:
a plurality of first barrier walls, extending along a first direction and arranged along a second direction, wherein the first direction and the second direction intersect; and
a plurality of second barrier walls, extending along the second direction and arranged along the first direction;
wherein the plurality of first barrier walls and the plurality of second barrier walls define a plurality of openings for defining pixel units, one pixel unit corresponds to one opening, and the pixel unit is in the corresponding opening;
the plurality of first barrier walls comprise:
two edge barrier walls which are two first barrier walls at two edges along the second direction;
a plurality of intermediate barrier walls between the two edge barrier walls; and
two separation barrier walls between the two edge barrier walls and respectively on both sides of the plurality of intermediate barrier walls along the second direction;
wherein heights of the second barrier wall, the edge barrier wall and the separation barrier wall each is greater than a height of the intermediate barrier wall.

2. The display panel according to claim 1, wherein the second barrier wall, the edge barrier wall and the separation barrier wall have equal heights.

3. The display panel according to claim 2, wherein the second barrier wall has a height of 0.6 μm to 1.5 μm, and the intermediate barrier wall has a height of 0.2 μm to 0.5 μm.

4. The display panel according to claim 2, wherein the plurality of first barrier walls further comprise:
at least one spacing barrier wall between the edge barrier wall and the separation barrier wall on at least one side along the second direction;
wherein a height of the spacing barrier wall is equal to the height of the second barrier wall.

5. The display panel according to claim 4, wherein the plurality of first barrier walls comprise a plurality of spacing barrier walls, and the plurality of spacing barrier walls are respectively between the edge barrier walls and the separation barrier walls on both sides along the second direction;
a quantity of the spacing barrier walls between the edge barrier walls and the separation barrier walls on the both sides along the second direction is equal; and
the height of the spacing barrier wall is equal to the height of the second barrier wall.

6. The display panel according to claim 1, wherein
colors of emergent light of the pixel units adjacent in the second direction are same, and
colors of emergent light of the pixel units adjacent in the first direction are different.

7. The display panel according to claim 6, wherein the pixel units are divided into first pixel units and second pixel units; the second pixel units are distributed on both sides of the first pixel units along the second direction;
the first pixel unit comprises an anode, a light emitting layer and a cathode arranged in sequence in the corresponding opening; the second pixel unit comprises a light emitting layer and a cathode arranged in sequence in the corresponding opening;
the pixel units between the two separation barrier walls are the first pixel units.

8. The display panel according to claim 7, wherein the pixel units between the separation barrier walls and the edge barrier walls on both sides along the second direction are the second pixel units.

9. The display panel according to claim 7, wherein at least one row of pixel units between the separation barrier wall and the edge barrier wall on at least one side along the second direction and adjacent to the separation barrier wall are the first pixel units; and the at least one row of pixel units is at least one row of pixel units arranged along the first direction.

10. The display panel according to claim 9, wherein the first barrier wall between the adjacent first pixel units and the second pixel units is a spacing barrier wall, and a height of the spacing barrier wall is greater than the height of the intermediate barrier wall.

11. The display panel according to claim 7, wherein a quantity of the second pixel units arranged along the second direction and located on any side of the first pixel units along the second direction is less than 6.

12. A display device comprising the display panel according to claim 1.

13. A method for manufacturing a display panel, comprising:
forming an anode of each pixel unit on a substrate;
forming a pixel definition layer on the substrate; wherein the pixel definition layer comprises: a plurality of first barrier walls and a plurality of second barrier walls; the plurality of first barrier walls extend along a first direction and are arranged along a second direction, the plurality of second barrier walls extend along the second direction and are arranged along the first direction; the first direction and the second direction intersect; the plurality of first barrier walls and the plurality of second barrier walls define a plurality of openings, and one opening corresponds to one anode; and
forming a light emitting layer and a cathode of each pixel unit on one side of the anode and the pixel definition layer facing away from the substrate;
wherein the plurality of first barrier walls comprise: two edge barrier walls, a plurality of intermediate barrier walls and two separation barrier walls; the two edge barrier walls are two first barrier walls at two edges along the second direction; the plurality of intermediate barrier walls are between the two edge barrier walls; the two separation barrier walls are between the two edge barrier walls and respectively on both sides of the plurality of intermediate barrier walls along the second direction; and heights of the second barrier wall, the edge barrier wall and the separation barrier wall each is greater than a height of the intermediate barrier wall.

14. The manufacturing method according to claim 13, wherein said forming of the pixel definition layer on the substrate comprises:
forming an entire lyophilic material layer on the substrate;
etching the lyophilic material layer to form the plurality of intermediate barrier walls;
forming an entire lyophobic material layer on one side of the plurality of intermediate barrier walls facing away from the substrate; and
etching the lyophobic material layer to form the plurality of second barrier walls, the two edge barrier walls and the two separation barrier walls; wherein the second barrier wall, the edge barrier wall and the separation barrier wall have equal heights.

15. The manufacturing method according to claim 14, wherein the plurality of first barrier walls further comprise: at least one spacing barrier wall; the at least one spacing barrier wall is between the edge barrier wall and the separation barrier wall on at least one side along the second direction; and
a height of the spacing barrier wall is equal to the height of the intermediate barrier wall;
said forming of the pixel definition layer on the substrate further comprises:
etching the lyophilic material layer to form the plurality of intermediate barrier walls and the at least one spacing barrier wall.

16. The manufacturing method according to claim 14, wherein said forming of the light emitting layer of each pixel unit on one side of the anode and the pixel definition layer facing away from the substrate comprises:
inkjet printing solution of the light emitting layer on the anode and the first barrier wall along the second direction; and
drying the solution of the light emitting layer to form the light emitting layer.

17. The display panel according to claim 2, wherein the plurality of first barrier walls further comprise:
at least one spacing barrier wall between the edge barrier wall and the separation barrier wall on at least one side along the second direction;
wherein a height of the spacing barrier wall is equal to the height of the intermediate barrier wall.

18. The manufacturing method according to claim 14, wherein the plurality of first barrier walls further comprise: at least one spacing barrier wall; the at least one spacing barrier wall is between the edge barrier wall and the separation barrier wall on at least one side along the second direction; and a height of the spacing barrier wall is equal to the height of the second barrier wall;
said forming of the pixel definition layer on the substrate further comprises:
etching the lyophobic material layer to form the plurality of second barrier walls, the two edge barrier walls, the two separation barrier walls and the at least one spacing barrier wall.
